(19) United States
(12) Patent Application Publication
(10) Pub. No.: US 2022/0383946 A1
(43) Pub. Date: Dec. 1, 2022

(54) MEMORY BIT CELL INCLUDING WRITE CONTROL CIRCUITS FOR COUPLING CONTROL OF VOLTAGE SOURCES TO AVOID OR REDUCE WRITE CONTENTION, AND RELATED METHODS

(71) Applicant: Microsoft Technology Licensing, LLC, Redmond, WA (US)

(72) Inventor: Amlan GHOSH, Mebane, NC (US)

(21) Appl. No.: 17/336,019

(22) Filed: Jun. 1, 2021

(51) Int. Cl. G11C 11/419; G11C 11/412

(52) U.S. Cl. CPC G11C 11/419; G11C 11/412

(57) ABSTRACT

Memory bit cells including write control circuits for coupling control of voltage sources to avoid or reduce write contention. The memory bit cells may be static random-access memory (SRAM) bit cells that include a true storage circuit and a complement storage circuit cross-coupled to generate complementary logical data states. Writing data into a memory bit cell circuit includes pulling up one of the true and complement storage circuits based on a pull-up voltage on a pull-up voltage rail while pulling down the opposite true or complementary output node based on a pull-down voltage on a pull-down voltage rail (i.e., to a logic ‘0’). The write control circuit can be controlled to decouple one of the true or complement storage circuits from a pull-up voltage rail or a pull-down voltage rail in response to a write operation to reduce or avoid a write contention.

### FIELD OF THE DISCLOSURE

The technology of the disclosure relates in general to memory bit cell circuits for storing data in memory arrays, and in particular to static random-access memory (SRAM) bit cell circuits that include mechanisms to reduce or avoid write contention.

### BACKGROUND

A memory bit cell circuit in an electronic device may store binary data in a storage circuit containing cross-coupled logic inverters. Logic inverters receive a binary value (e.g., logic ‘0’ or logic ‘1’) as an input and generate the opposite binary value as an output. In cross-coupled inverters, an output of a first inverter is coupled to the input of a second inverter and the output of the second inverter is coupled to the input of the first inverter. A logic ‘0’ on the input of the first inverter generates a logic ‘1’ on the input of the second inverter, which in turn continues to generate a logic ‘0’ on the input of the first inverter. In this regard, the first and second inverters reinforce each other. Writing new data to the memory bit cell circuit includes changing the data stored in the storage circuit, which may include forcing a new value onto the input of one of the inverters as the other inverter tries to maintain the same value. Conflicting forces that may occur in a memory bit cell circuit during a memory write operation may he referred to as a “write contention.”

FIG. 1 is a circuit diagram of an eight (8) transistor (8T) static random-access memory (SRAM) bit cell 100 to illustrate a write contention between an N-type field effect transistor (FET) (NFET) access transistor 102 and a P-type FET (PFET) 104 in an inverter 106. For example, a logic ‘1’ is stored in a true storage node 108 (T=1) (and a logic ‘0’ is stored in a complement storage node 108′ (C=0)). In a write operation in which a data of logic ‘0’ is placed on a bitline 110 to be written to the true storage node 108 and a data of logic ‘1’ is placed on a complement bitline 110′ to be written to the complement storage node 108′, the NFET access transistor 102 discharges the true storage node 108 to the bitline 110 to write a logic ‘0’ to the true storage node 108. The NFET access transistor 102 is capable of passing a strong logic ‘0’. However, the logic ‘0’ stored in the complement storage node 108′ can cause the PFET 104 to overcome the drive strength of the NFET access transistor 102. The PFET 104 may continue to provide charge to the true storage node 108 more quickly than the NFET access transistor 102 can discharge the true storage node 108. Thus, the true storage node may be charged based on voltage V_{DD} (i.e., a logic ‘1’), causing the true storage node 108 to unexpectedly remain at a logic ‘1’ and the complement storage node 108′ to remain at a logic ‘0’ after the write operation. In this example, the logic ‘0’ is not written to the true storage node 108 and a logic ‘1’ is not written to the complement storage node 108′.

Memory arrays of memory bit cell circuits that incur write contention in write operations may excessively consume power and may also have high instances of errors in data read from the memory array due to failed write operations.

### SUMMARY

Exemplary aspects disclosed herein include memory bit cells including write control circuits for coupling control of voltage sources to avoid or reduce write contention. Related methods are also disclosed. For example, the memory bit cells may be static random-access memory (SRAM) bit cells that include a true storage circuit and a complement storage circuit that are cross-coupled to generate complementary voltage (i.e., logic) states in the form of complementary voltage levels on complementary output nodes in response to a write operation. For example, in a write operation, data is written into a memory bit cell circuit by activating the storage circuits to pull up a true or complementary data output node to a pull-up voltage on a pull-up voltage rail (i.e., to a logic ‘1’) while pulling down the respective, opposite complementary or true data output node to a pull-down voltage on a pull-down voltage rail (i.e., to a logic ‘0’). In an exemplary aspect, the memory bit cell includes a write control circuit coupled between the storage circuits and either a pull-up voltage rail or a pull-down voltage rail. The write control circuit can be controlled to selectively couple or decouple each of the storage circuits to the coupled pull-up or pull-down voltage rail in response to a write operation to reduce or avoid a write contention.

For example, the write control circuit can be coupled to the true and complement storage circuits and a pull-up voltage rail to decouple one of the true and complement storage circuits from the pull-up voltage rail to avoid or reduce a write contention that may otherwise occur as a result of a pull-up transistor in the one storage circuit pulling up the voltage of an output node as the output node is simultaneously being pulled down. As another example, the write control circuit can be coupled to the true and complement storage circuits and a pull-down voltage rail to avoid or reduce a write contention that may otherwise occur as a result of a pull-down transistor in one of the true and complement storage circuits pulling down the voltage of the output node as the output node is being pulled up. In this manner, unnecessary power consumption and write data errors resulting from write operations to the memory array circuit can be reduced.

In one example, the write control circuit may be configured to mask new data from being written to the memory bit cell when the write word signal is activated for selective writing to memory bit cells in a row of a memory bit cell array.

In an exemplary aspect, a memory array circuit including a plurality of SRAM bit cell circuits is disclosed. Each of the SRAM bit cell circuits includes a true storage circuit comprising a true output node, a true pull-up circuit coupled to the true output node, and a true pull-down circuit coupled to the true output node. Each of the SRAM bit cell circuits includes a complement storage circuit comprising a complement output node, a complement pull-up circuit coupled to the complement output node, and a complement pull-down circuit coupled to the complement output node. Each of the SRAM bit cell circuits includes a write control circuit comprising a true write control circuit coupled between the true pull-up circuit and a pull-up voltage rail, and a complement write control circuit coupled between the complement pull-up circuit and the pull-up voltage rail. The write control circuit is configured to couple the true pull-up circuit to the pull-up voltage rail in response to a write operation to the true output node based on a pull-up voltage on the pull-up voltage rail and decouple the complement pull-up circuit from the pull-up voltage rail in response to a write operation to the complement output node based on a pull-down voltage on a pull-down voltage rail.

In another exemplary aspect, a method in a memory array circuit comprising a plurality of SRAM bit cell circuits is disclosed. The method comprises coupling a true pull-up circuit to a true output node, coupling a true pull-down circuit to the true output node, coupling a complement pull-up circuit to a complement output node, and coupling a complement pull-down circuit to the complement output node. The method further comprises coupling the true pull-up circuit to a pull-up voltage rail in response to a write operation to the true output node based on a pull-up voltage on the pull-up voltage rail and decoupling the complement pull-up circuit from the pull-up voltage rail in response to a write operation to the complement output node based on a pull-down voltage on a pull-down voltage rail.

In another exemplary aspect, a memory array circuit comprising a plurality of SRAM bit cell circuits is disclosed. Each of the SRAM bit cell circuits comprises a true storage circuit, comprising a true output node, a true pull-up circuit coupled to the true output node, and a true pull-down circuit coupled to the true output node. Each of the SRAM bit cell circuits comprises a complement storage circuit, comprising a complement output node, a complement pull-up circuit coupled to the complement output node, and a complement pull-down circuit coupled to the complement output node. Each of the SRAM bit cell circuits comprises a write control circuit comprising a true write control circuit coupled between the true pull-down circuit and a pull-down voltage rail and a complement write control circuit coupled between the complement pull-down circuit and the pull-down voltage rail. The write control circuit is configured to couple the true pull-down circuit to the pull-down voltage rail in response to a write operation to the true output node based on a pull-down voltage on the pull-down voltage rail and decouple the complement pull-down circuit from the pull-down voltage rail in response to a write operation to the complement output node based on a pull-up voltage on a pull-up voltage rail.

In another exemplary aspect, a method in a memory array circuit comprising a plurality of SRAM bit cell circuits is disclosed. The method comprises coupling a true pull-up circuit to a true output node, coupling a true pull-down circuit to the true output node, coupling a complement pull-up circuit to a complement output node, and coupling a complement pull-down circuit to the complement output node. The method comprises coupling the true pull-down circuit to a pull-down voltage rail in response to a write operation to the true output node based on a pull-down voltage on the pull-down voltage rail and decoupling the complement pull-down circuit from the pull-down voltage rail in response to a write operation to the complement output node based on a pull-up voltage on a pull-up voltage rail.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an eight (8) transistor (8T) static random-access memory (SRAM) bit cell circuit provided for reference to describe an example of write contention in a write operation;

FIG. 2A is a schematic diagram of an exemplary SRAM bit cell circuit including a storage circuit and a write control circuit configured to decouple, from a pull-up voltage rail, a pull-up circuit coupled to a first output node in the storage circuit in response to a write operation to a second output node in the storage circuit to reduce or avoid write contention;

FIG. 2B is a schematic diagram of the exemplary SRAM bit cell circuit in FIG. 2A including detail of the write control circuit configured to decouple a pull-up circuit from a pull-up voltage rail in response to a write operation;

FIG. 3A is a schematic diagram of another exemplary SRAM bit cell circuit including a storage circuit and a write control circuit configured to decouple, from a pull-down voltage rail, a pull-down circuit coupled to a first output node in the storage circuit in response to a write operation to a second output node in the storage circuit to reduce or avoid write contention;

FIG. 3B is a schematic diagram of the exemplary SRAM bit cell circuit in FIG. 3A including detail of the write control circuit configured to decouple a pull-down circuit from a pull-down voltage rail in response to a write operation;

FIGS. 4A and 4B illustrate a flow chart of a method in an SRAM bit cell circuit of a memory array circuit including a plurality of the SRAM bit cell circuits in FIGS. 2A, 2B, 3A, and 3B including write control circuits configured to reduce or avoid write contention in a write operation;

FIG. 5 is a schematic diagram of a memory array circuit including the SRAM bit cell circuits in FIGS. 2A, 2B, 3A, and 3B including write control circuits configured to reduce or avoid write contention in a write operation according to the method in FIGS. 4A-4B; and

FIG. 6 is block diagram of an exemplary processor-based system including a plurality of devices coupled to a system bus, wherein the processor-based system includes a memory array circuit including SRAM bit cell circuits including write control circuits configured to reduce or avoid write contention in a write operation in the SRAM bit cell circuits, as illustrated in FIGS. 2A, 2B, 3A, and 3B.

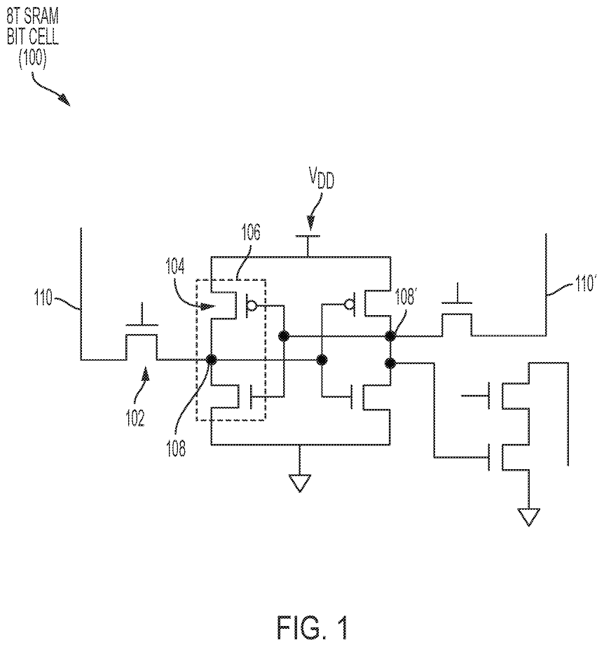

### DETAILED DESCRIPTION

Exemplary aspects disclosed herein include memory bit cells including write control circuits for coupling control of voltage sources to avoid or reduce write contention. Related methods are also disclosed. For example, the memory bit cells may be static random-access memory (SRAM) bit cells that include a true storage circuit and a complement storage circuit that are cross-coupled to generate complementary voltage (i.e., logic) states in the form of complementary voltage levels on complementary output nodes in response to a write operation. For example, in a write operation, data is written into a memory bit cell circuit by activating the storage circuits to pull up a true or complementary data output node to a pull-up voltage on a pull-up voltage rail (i.e., to a logic ‘1’) while pulling down the respective, opposite complementary or true data output node to a pull-down voltage on a pull-down voltage rail (i.e., to a logic ‘0’). In an exemplary aspect, the memory bit cell includes a write control circuit coupled between the storage circuits and either a pull-up voltage rail or a pull-down voltage rail. The write control circuit can be controlled to selectively couple or decouple each of the storage circuits to the coupled pull-up or pull-down voltage rail in response to a write operation to reduce or avoid a write contention.

For example, the write control circuit can be coupled to the true and complement storage circuits and a pull-up voltage rail to decouple one of the true and complement storage circuits from the pull-up voltage rail to avoid or reduce a write contention that may otherwise occur as a result of a pull-up transistor in the one storage circuit pulling up the voltage of an output node as the output node is simultaneously being pulled down. As another example, the write control circuit can be coupled to the true and complement storage circuits and a pull-down voltage rail to avoid or reduce a write contention that may otherwise occur as a result of a pull-down transistor in one of the true and complement storage circuits pulling down the voltage of the output node as the output node is being pulled up. In this manner, unnecessary power consumption and write data errors resulting from write operations to the memory array circuit can be reduced.

In one example, the write control circuit may be configured to mask new data from being written to the memory bit cell when the write word signal is activated for selective writing to memory bit cells in a row of a memory bit cell array.

Existing mechanisms and methods employed to address write contention are primarily directed to positively or negatively boosting voltages and/or adjusting relative sizes of transistors in an SRAM bit cell circuit in effort to mitigate the effects of write contention. Although such efforts generally reduce the severity of the problem, they are not directed to eliminating a voltage source that hinders the change of data state in a node of the SRAM bit cell circuit during a write operation.

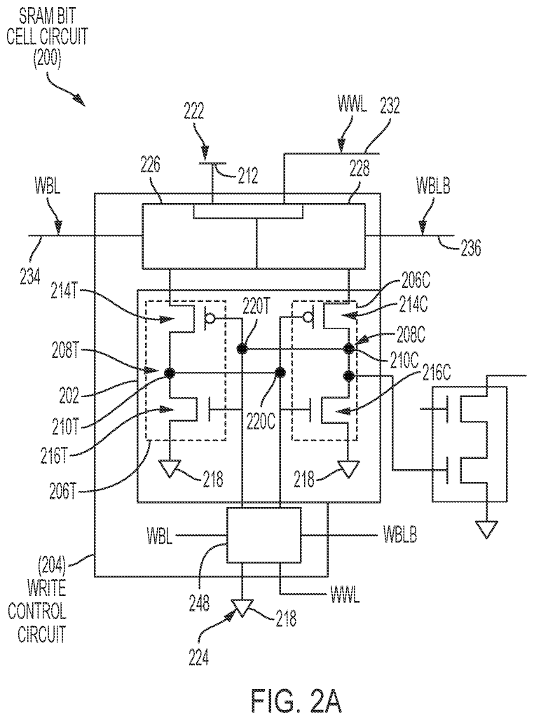

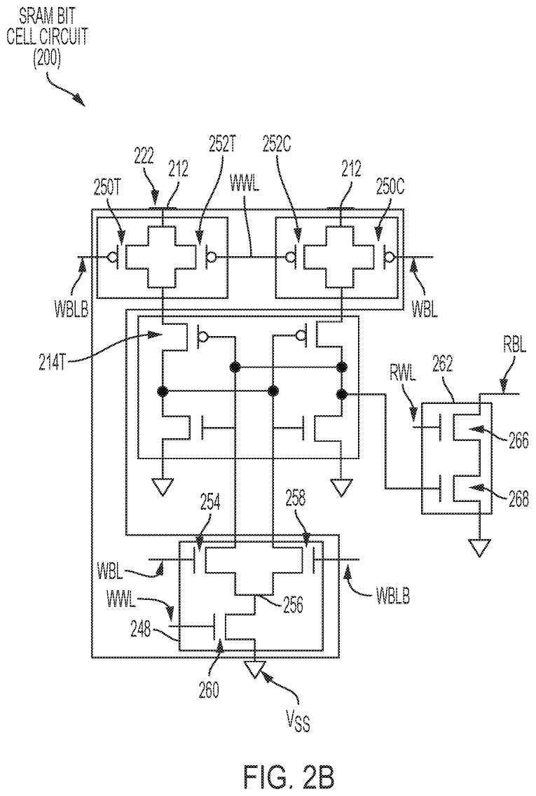

FIG. 2A is a schematic diagram of an SRAM bit cell circuit 200 including a storage circuit 202 and a write control circuit 204 configured to reduce or avoid write contention when writing data into the storage circuit 202. The storage circuit 202 includes a true storage circuit 206T and a complement storage circuit 206C, which are cross-coupled to store a true data state 208T in a true output node 210T and a complement data state 208C in a complement output node 210C. The write control circuit 204 is configured to, in response to a write operation writing a logic ‘1’ to one of the true storage circuit 206T and the complement storage circuit 206C, decouple the opposite storage circuit (206C or 206T) from a pull-up voltage rail 212. In this manner, a source of write contention may be decoupled from the storage circuit 202 to reduce or avoid write contention during a write operation. In this context, the true storage circuit 206T and true output node 210T are referred to as opposites to the complement storage circuit 206C and complement output node 210C.

Before explaining aspects of the exemplary write control circuit 204 further, some context and definitions are first provided. The true storage circuit 206T includes the true output node 210T and a true pull-up circuit 214T coupled to the true output node 210T. The true storage circuit 206T also includes a true pull-down circuit 216T coupled to the true output node 210T and to a pull-down voltage rail 218. The complement storage circuit 206C includes a complement pull-up circuit 214C coupled to the complement output node 210C. The complement storage circuit 206C includes a complement pull-down circuit 216C coupled to the complement output node 210C and to the pull-down voltage rail 218. With regard to the storage circuit 202, the term “cross-coupled” indicates that the true output node 210T of the true storage circuit 206T is coupled to an input 220C of the complement storage circuit 206C and the complement output node 210C of the complement storage circuit 206C is coupled to an input 220T of the true storage circuit 206T.

The write control circuit 204 decouples one of the true storage circuit 206T and the complement storage circuit 206C from the pull-up voltage rail 212 by turning off a conductive path from the pull-up voltage rail 212, as explained further below. The pull-up voltage rail 212 may be an electrical node that provides a pull-up voltage 222, which may be referred to as a power supply voltage (e.g., V_{DD}). The pull-up voltage 222 may have a positive voltage potential relative to a pull-down voltage 224 on the pull-down voltage rail 218. The pull-down voltage 224 may also be referred to herein as a ground supply voltage (e.g., V_{SS}).

The storage circuit 202 may store the data states 208T and 208C, which may include charging one of the true output node 210T and the complement output node 210C based on the pull-up voltage 222 and discharging the opposite output node. Resistance in the true and complement storage circuits 206T and 206C may prevent the true output node 210T and the complement output node 210C from being fully charged to the pull-up voltage 222. Nonetheless, a voltage level on one of the true output node 210T and the complement output node 210C may indicate a first logic state (e.g., binary state), and another voltage on the opposite one of the true output node 210T and the complement output node 210C may indicate a second logic state. Assignment of a logic state to a voltage may be arbitrary. For example, a positively charged state (based on the pull-up voltage 222) may correspond to a logic ‘1’ and a discharged state (based on the pull-down voltage 224) may correspond to a logic ‘0’. This convention is used herein. However, a positively charged state may alternatively be assigned to a logic ‘0’ and a discharged state may be assigned to a logic ‘1’. A write operation to the storage circuit 202 may include charging one of the true output node 210T and the complement output node 210C and discharging the opposite one. The write operation may include coupling one of the true pull-up circuit 214T and the complement pull-up circuit 214C to the pull-up voltage rail 212.

With further reference to FIG. 2A, the write control circuit 204 includes a true write control circuit 226 and a complement write control circuit 228. The true write control circuit 226 is coupled between the true pull-up circuit 214T and the pull-up voltage rail 212. The complement write control circuit 228 is coupled between the complement pull-up circuit 214C and the pull-up voltage rail 212. In one example, the write control circuit 204 is configured to couple the true pull-up circuit 214T to the pull-up voltage rail 212 in response to a write operation to the true output node 210T based on the pull-up voltage 222 on the pull-up voltage rail 212. In this example, the write control circuit 204 is further configured to decouple the complement pull-up circuit 214C from the pull-up voltage rail 212 in response to a write operation to the complement output node 210C based on the pull-down voltage 224 on the pull-down voltage rail 218.

In another example, the write control circuit 204 is configured to couple the complement pull-up circuit 214C to the pull-up voltage rail 212 in response to a write operation to the complement output node 210C based on the pull-up voltage 222 on the pull-up voltage rail 212. In this example, the write control circuit 204 is further configured to decouple the true pull-up circuit 214T from the pull-up voltage rail 212 in response to a write operation to the true output node 210T based on the pull-down voltage 224 on the pull-down voltage rail 218.

A write operation to the storage circuit 202 is indicated to the write control circuit 204 by a write word signal WWL, a true write bit signal WBL and a complement write bit signal WBLB. The write word signal WWL is provided to the write control circuit 204 on a write word line 232. The true write bit signal WBL and the complement write bit signal WBLB are provided to the write control circuit 204 on a true write bit line 234 and a complement write bit line 236, respectively. Operation of the SRAM bit cell circuit 200 in response to the write word signal WWL, the true write bit signal WBL, and the complement write bit signal WBLB is explained by way of examples below.

The write word signal WWL may be provided to the SRAM bit cell circuit 200 in an active state 238A (not shown) and an inactive state 238I (not shown). Each of the true write bit signal WBL and the complement write bit signal WBLB may be provided, independent of each other, in one of a first write state 240 (not shown) and a second write state 242 (not shown). The first write state 240 may correspond to a logic ‘0’ in this example, and the second write state may correspond to a logic ‘1’. However, the first and second write states 240 and 242 may correspond to logic ‘1’ and logic ‘0’, respectively, in some examples. A write operation may be indicated by the write word signal WWL being in or comprising the active state 238A. However, the results of the write operation are determined by a true write control circuit 226 and a complement write control circuit 228 in the write control circuit 204.

A write operation to store a logic ‘1’ in the true output node 210T is described as a first example. It is assumed that, prior to the write operation, the true output node 210T is storing a logic ‘0’, which is based on the pull-down voltage 224, and the complement output node 210C is storing a logic ‘1’, based on the pull-up voltage 222. In response to the write word signal WWL being in the active state 238A, indicating a write operation, the true write control circuit 226 is configured to couple the true pull-up circuit 214T to the pull-up voltage rail 212 in response to the complement write bit signal WBLB in the first write state 240. As noted above, the complement output node 210C is coupled to the input 220T of the true storage circuit 206T. Since the complement output node is at a logic ‘1’ prior to the write operation, the true pull-up circuit 214T is turned off. Thus, there is initially no change to the true output node 210T. The true output node 210T remains at a logic ‘0’, which keeps the complement pull-up circuit 214C turned on, coupling the complement output node 210C to the pull-up voltage rail 212.

However, in this write operation the complement write control circuit 228 is configured to decouple the complement pull-up circuit 214C from the pull-up voltage rail 212 in response to the true write bit signal WBL comprising the second write state 242. Furthermore, the write control circuit 204 includes a write mask circuit 248 configured to couple the complement output node 210C to the pull-down voltage rail 218 in response to the write operation to the complement output node 210C based on the pull-down voltage 224 on the pull-down voltage rail 218. This write operation to the complement output node 210C is further indicated by the complement write bit signal WBLB being in the second write state 242, which discharges the complement output node 210C from a logic ‘1’ to a logic ‘0’. Since the complement write control circuit 228 has decoupled the complement pull-up circuit 214C from the pull-up voltage rail 212, a voltage source for the pull-up voltage 222 has been blocked, which reduces or avoids a source of contention with discharging the complement output node 210C. As the complement output node 210C discharges, transitioning from a logic ‘1’ to logic ‘0’, the true pull-up circuit 214T is turned on. Thus, the true pull-up circuit 214T couples the true output node 210T to the pull-up voltage rail 212, which charges the true output node 210T to a logic ‘1’ based on the pull-up voltage 222. The true output node 210T charging to the logic ‘1’ turns off the complement pull-up circuit 214C. Therefore, the complement output node 210C will remain discharged, at logic ‘0’, independent of the complement write control circuit 228 after the write operation is complete.

In a second example of a write operation, in which a logic ‘1’ is written to the complement output node 210C, the write word signal WWL is again provided on the write word line 232 in the active state 238A. In response to the write word signal WWL being in the active state 238A, the true write control circuit 226 is configured to decouple the true pull-up circuit 214T from the pull-up voltage rail 212 in response to the complement write bit signal WBLB being in the second write state 242. In addition, in the second example of a write operation, the complement write control circuit 228 is configured to couple the complement pull-up circuit 214C to the pull-up voltage rail 212 in response to the true write bit signal WBL being in the first write state 240. The write mask circuit 248 is configured to couple the true output node 210T to the pull-down voltage rail 218 in response to the write operation to the true output node 210T based on the pull-down voltage 224 on the pull-down voltage rail 218. This write operation to the true output node 210T may be further indicated by the true write bit signal WBL being in the second write state 242, which discharges the true output node 210T from a logic ‘1’ to a logic ‘0’. The true output node 210T at a logic ‘0’ turns on the complement pull-up circuit 214C to charge the complement output node 210C to a logic ‘1’. With the true pull-up circuit 214T decoupled from the pull-up voltage rail 212 by the true write control circuit 226, write contention is reduced or avoided in the discharging true output node 210T.

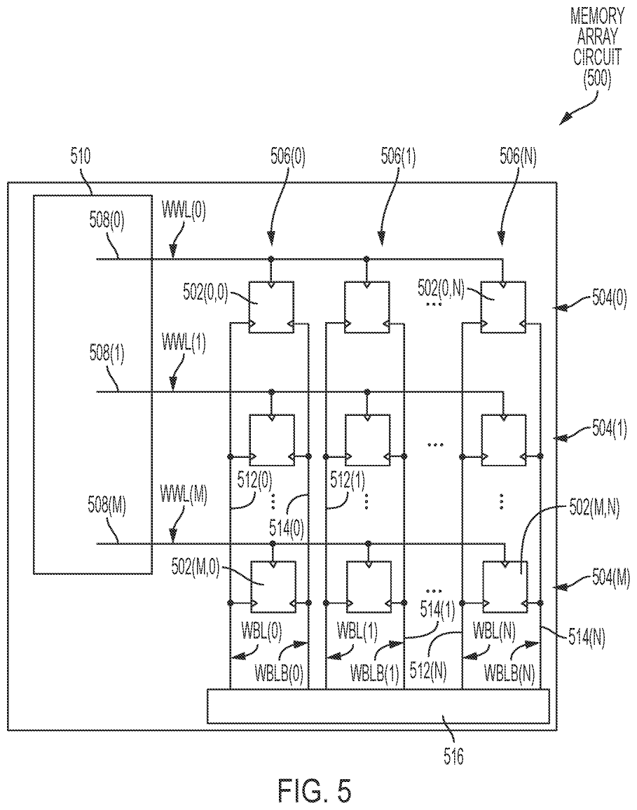

No write operation occurs in the SRAM bit cell circuit 200 in response to the write word signal WWL being in the inactive state 238I. In such condition, the true write control circuit 226 is configured to couple the true pull-up circuit 214T to the pull-up voltage rail 212 and the complement write control circuit 228 is configured to couple the complement pull-up circuit 214C to the pull-up voltage rail 212. Another condition of the write word signal WWL, the true write bit signal WBL, and the complement write bit signal WBLB in a memory bit cell circuit corresponding to a third example of a write operation is described further below, in reference to FIG. 5.

Referring to FIG. 2B, the true write control circuit 226 includes a transistor 250T configured to couple the true pull-up circuit 214T to the pull-up voltage rail 212 in response to the complement write bit signal WBLB, and a transistor 252T configured to couple the true pull-up circuit 214T to the pull-up voltage rail 212 in response to the write word signal WWL. The complement write control circuit 228 includes a transistor 250C configured to couple the complement pull-up circuit 214C to the pull-up voltage rail 212 in response to the true write bit signal WBL, and a transistor 252C configured to couple the complement pull-up circuit 214C to the pull-up voltage rail 212 in response to the write word signal WWL. In FIG. 2B, the transistors 250T, 252T, 250C, and 252C of the true write control circuit 226 and the complement write control circuit 228 may be P-type metal-oxide-semiconductor (MOS) (PMOS) transistors, which include semiconductor material doped with a trivalent impurity (e.g., boron, gallium, indium, etc.), because PMOS transistors can provide a strong pull-up connection to the pull-up voltage rail 212. However, N-type MOS (NMOS) transistors may alternatively be employed in the true write control circuit 226 and the complement write control circuit 228 in some examples.

The write mask circuit 248 includes a transistor 254 configured to couple to the true output node 210T to a write mask node 256 in response to the true write bit signal WBL being in the second write state 242. The write mask circuit 248 also includes a transistor 258 configured to couple the complement output node 210C to the write mask node 256 in response to the complement write bit signal WBLB comprising the second write state 242. The write mask circuit 248 includes a transistor 260 configured to couple the write mask node 256 to the pull-down voltage rail 218 in response to the write word signal WWL being in the active state 238A. The write mask circuit 248 couples one of the true output node 210T and the complement output node 210C to the pull-down voltage rail 218 in response to a write operation indicated by the active state 238A of the write word signal WWL. The transistors 254, 258, and 260 of the write mask circuit 248 may be N-type transistors doped with a pentavalent impurity (e.g., phosphorous, arsenic, antimony, etc.) because NMOS transistors can provide a strong pull-down connection to the pull-down voltage rail 218. However, PMOS transistors may be employed in the true write control circuit 226 and the complement write control circuit 228.

The SRAM bit cell circuit 200 also includes an example of a read control circuit 262. In the example in FIG. 2B, the read control circuit 262 is configured to couple a read bit line RBL to the pull-down voltage rail 218 in response to a read word operation. The read word operation is indicated by a read word signal RWL and the complement data state 208C on the complement output node 210C. For example, in response to the read word signal RWL turning on a transistor 266 and the complement data state 208C comprising a logic ‘1’, which turns on a transistor 268, the read bit line RBL is coupled to the pull-down voltage rail 218, discharging the read bit line RBL to the logic ‘0’ state, which corresponds to the true data state 208T on the true output node 210T. In the case of a logic ‘0’ on the complement output node 210C when the read word signal RWL turns on the transistor 266, the read bit line RBL is not discharged, and remains at a logic ‘1’, which corresponds to the true data state 208T.

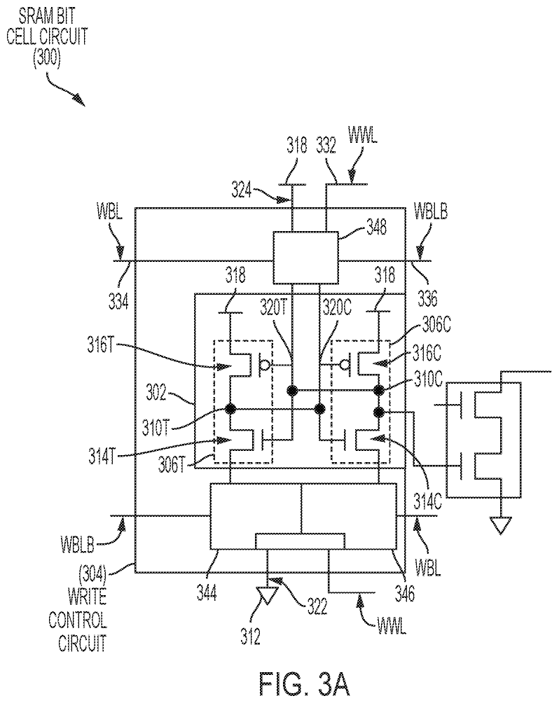

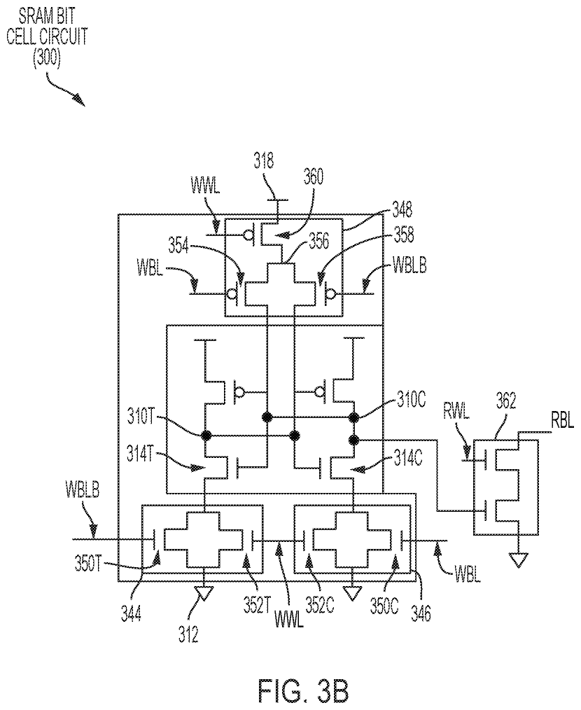

FIG. 3A is a schematic diagram of another exemplary SRAM bit cell circuit 300 including a storage circuit 302 and a write control circuit 304 configured to reduce or avoid write contention when writing data into the storage circuit 302. The storage circuit 302 includes a true storage circuit 306T and a complement storage circuit 306C, which are cross-coupled to store a true data state 308T (not shown) in a true output node 310T and a complement data state 308C (not shown) in a complement output node 310C. The write control circuit 304 is configured to, in response to a write operation writing a logic ‘0’ to one of the true storage circuit 306T and the complement storage circuit 306C, decouple the opposite storage circuit (306C or 306T) from a pull-down voltage rail 312. In this manner, a source of write contention may be decoupled from the storage circuit 302 to reduce or avoid write contention during a write operation. In this context, the true storage circuit 306T and true output node 310T may be referred to as opposites to the complement storage circuit 306C and the complement output node 310C.

The true storage circuit 306T includes a true pull-down circuit 314T to couple the true output node 310T to the pull-down voltage rail 312. The true storage circuit 306T includes a true pull-up circuit 316T coupled to the true output node 310T and to a pull-up voltage rail 318. The complement storage circuit 306C includes a complement pull-up circuit 316C coupled to the complement output node 310C. The complement storage circuit 306C also includes a complement pull-down circuit 314C coupled to the complement output node 310C and to the pull-down voltage rail 312. The true output node 310T of the true storage circuit 306T is coupled to an input 320C of the complement storage circuit 306C. The complement output node 310C of the complement storage circuit 306C is coupled to an input 320T of the true storage circuit 306T.

The write control circuit 304 decouples one of the true storage circuit 306T and the complement storage circuit 306C from the pull-down voltage rail 312 by turning off a conductive path to the pull-down voltage rail 312, as explained further below. The pull-down voltage rail 312 may be an electrical node that provides a pull-down voltage 322, which may be referred to as a ground supply voltage (e.g., V_{SS}). The pull-down voltage 322 may have a negative voltage potential relative to a pull-up voltage 324 on the pull-up voltage rail 318. The pull-up voltage 324 may also be referred to herein as a power supply voltage (e.g., V_{DD}).

In response to a write operation, the storage circuit 302 may store the data states 308T and 308C, which may include discharging one of the true output node 310T and the complement output node 310C based on the pull-up voltage 324 and charging the opposite output node based on the pull-up voltage 324. The write operation may include coupling one of the true pull-down circuit 314T and the complement pull-down circuit 314C to the pull-down voltage rail 312. The write control circuit 304 includes a true write control circuit 344 and a complement write control circuit 346. The true write control circuit 344 is coupled between the true pull-down circuit 314T and the pull-down voltage rail 312. The complement write control circuit 346 is coupled between the complement pull-down circuit 314C and the pull-down voltage rail 312. In one example, the write control circuit 304 is configured to couple the true pull-down circuit 314T to the pull-down voltage rail 312 in response to a write operation to the true output node 310T based on the pull-down voltage 322 on the pull-down voltage rail 312. In this example, the write control circuit 304 is further configured to decouple the complement pull-down circuit 314C from the pull-down voltage rail 312 in response to a write operation to the complement output node 310C based on the pull-up voltage 324 on the pull-up voltage rail 318.

In another example, the write control circuit 304 is configured to couple the complement pull-down circuit 314C to the pull-down voltage rail 312 in response to a write operation to the complement output node 310C based on the pull-down voltage 322 on the pull-down voltage rail 312. In this example, the write control circuit 304 is further configured to decouple the true pull-down circuit 314T from the pull-down voltage rail 312 in response to a write operation to the true output node 310T based on the pull-up voltage 324 on the pull-up voltage rail 318.

A write operation to the storage circuit 302 is indicated to the write control circuit 304 by a write word signal WWL, a true write bit signal WBL, and a complement write bit signal WBLB. The write word signal WWL is provided to the write control circuit 304 on a write word line 332. The true write bit signal WBL and the complement write bit signal WBLB are provided to the write control circuit 304 on a true write bit line 334 and a complement write bit line 336, respectively. Operation of the SRAM bit cell circuit 300 in response to the write word signal WWL, the true write bit signal WBL, and the complement write bit signal WBLB is explained by way of the examples below.

The write word signal WWL may be provided to the SRAM bit cell circuit 300 in an active state 338A (not shown) and an inactive state 338I (not shown). In this example, an active state of the write word line 332 may correspond to a logic ‘0’ and an inactive state may correspond to a logic ‘1’. Each of the true write bit signal WBL and the complement write bit signal WBLB may be provided, independent of each other, in one of a first write state 340 (not shown) and a second write state 342 (not shown). A write operation may be indicated by the write word signal WWL being in or comprising the active state 338A. The results of the write operation may be determined by a true write control circuit 344 and a complement write control circuit 346 in the write control circuit 304.

A write operation to store a logic ‘0’ in the true output node 310T is described as a first example. It is assumed that, prior to the write operation, the true output node 310T is storing a logic ‘1’, which is based on the pull-up voltage 324, and the complement output node 310C is storing a logic ‘0’, based on the pull-down voltage 322. In response to the write word signal WWL being in the active state 338A, indicating a write operation, the true write control circuit 344 is configured to couple the true pull-down circuit 314T to the pull-down voltage rail 312 in response to the complement write bit signal WBLB in the first write state 340. As noted above, the complement output node 310C is coupled to the input 320T of the true storage circuit 306T. Since the complement output node is at a logic ‘0’ prior to the write operation, the true pull-down circuit 314T is turned off. Thus, there is initially no change to the true output node 310T in response to the write word line WWL. The true output node 310T remains at a logic ‘1’ which keeps the complement pull-down circuit 314C turned on, coupling the complement output node 310C to the pull-down voltage rail 312.

In this write operation the complement write control circuit 346 is configured to decouple the complement pull-down circuit 314C from the pull-down voltage rail 312 in response to the true write bit signal WBL comprising the second write state 242. Furthermore, the write control circuit 304 includes a write mask circuit 348 configured to couple the complement output node 310C to the pull-up voltage rail 318 in response to the write operation to the complement output node 310C based on the pull-up voltage 324 on the pull-up voltage rail 318. This write operation to the complement output node 310C is further indicated by the complement write bit signal WBLB being in the second write state 342, which charges the complement output node 310C from a logic ‘0’ to a logic ‘1’. Since the complement write control circuit 346 has decoupled the complement pull-down circuit 314C from the pull-down voltage rail 312, a voltage source for the pull-down voltage 322 is blocked, which reduces or avoids a source of contention with the pull-up voltage rail 318 charging the complement output node 310C. As the complement output node 310C charges, transitioning from a logic ‘0’ to logic ‘1’, the true pull-down circuit 314T is turned on. Thus, the true pull-down circuit 314T couples the true output node 310T to the pull-down voltage rail 312, which discharges the true output node 310T to a logic ‘0’ based on the pull-down voltage 222. The true output node 310T discharging to the logic ‘0’ turns off the complement pull-down circuit 314C. Therefore, the complement output node 310C will remain charged, at logic ‘1’, independent of the complement write control circuit 346 after the write operation is complete.

In a second example of a write operation, in which a logic ‘0’ is written to the complement output node 310C, the write word signal WWL is again provided on the write word line 332 in the active state 338A. In response to the write word signal WWL being in the active state 338A, the true write control circuit 344 is configured to decouple the true pull-down circuit 314T from the pull-down voltage rail 312 in response to the complement write bit signal WBLB being in the second write state 342. In addition, in the second example of a write operation, the complement write control circuit 346 is configured to couple the complement pull-down circuit 314C to the pull-down voltage rail 312 in response to the true write bit signal WBL being in the first write state 340. The write mask circuit 348 is configured to couple the true output node 310T to the pull-up voltage rail 318 in response to the write operation to the true output node 310T based on the pull-up voltage 324 on the pull-up voltage rail 318. This write operation to the true output node 310T may be further indicated by the true write bit signal WBL being in the second write state 342, which charges the true output node 310T from a logic ‘0’ to a logic ‘1’. The true output node 310T at a logic ‘1’ turns on the complement pull-down circuit 314C to discharge the complement output node 310C to a logic ‘0’. With the true pull-down circuit 314T decoupled from the pull-down voltage rail 312 by the true write control circuit 344, write contention is reduced or avoided in writing a logic ‘0’ to the true output node 310T.

No write operation occurs in the SRAM bit cell circuit 300 in response to the write word signal WWL being in the inactive state 338I. In such condition, the true write control circuit 344 is configured to couple the true pull-down circuit 314T to the pull-down voltage rail 312 and the complement write control circuit 346 is configured to couple the complement pull-down circuit 314C to the pull-down voltage rail 312. Another condition of the write word signal WWL, the true write bit signal WBL, and the complement write bit signal WBLB in a memory bit cell circuit corresponding to a third example of a write operation is described further below, in reference to FIG. 5.

Referring to FIG. 3B, the true write control circuit 344 includes a transistor 350T configured to couple the true pull-down circuit 314T to the pull-down voltage rail 312 in response to the complement write bit signal WBLB, and a transistor 352T configured to couple the true pull-down circuit 314T to the pull-down voltage rail 312 in response to the write word signal WWL. The complement write control circuit 346 includes a transistor 350C configured to couple the complement pull-down circuit 314C to the pull-down voltage rail 312 in response to the true write bit signal WBL, and a transistor 352C configured to couple the complement pull-down circuit 314C to the pull-down voltage rail 312 in response to the write word signal WWL. In FIG. 3B, the transistors 350T, 352T of the true write control circuit 344 and transistors 350C and 352C of the complement write control circuit 346 may be NMOS transistors that can provide a strong pull-down connection to the pull-down voltage rail 312. However, PMOS transistors may alternatively be employed in the true write control circuit 344 and the complement write control circuit 346 in some examples.

The write mask circuit 348 includes a transistor 354 configured to couple the true output node 310T to a write mask node 356 in response to the true write bit signal WBL being in the second write state 342. The write mask circuit 348 also includes a transistor 358 configured to couple the complement output node 310C to the write mask node 356 in response to the complement write bit signal WBLB comprising the second write state 342. The write mask circuit 348 includes a transistor 360 configured to couple the write mask node 356 to the pull-up voltage rail 318 in response to the write word signal WWL being in the active state 338A. The write mask circuit 348 couples one of the true output node 310T and the complement output node 310C to the pull-up voltage rail 318 in response to a write operation indicated by the active state 338A of the write word signal WWL. The transistors 354, 358, and 360 of the write mask circuit 348 may be PMOS transistors that can provide a strong pull-up connection to the pull-up voltage rail 318. However, NMOS transistors may be employed in the true write control circuit 344 and the complement write control circuit 346.

The SRAM bit cell circuit 300 also includes an example of a read control circuit 362. Operation of the read control circuit 362 in FIGS. 3A and 3B corresponds to operation of the read control circuit 262, as described above, such that the true data state 308T of the true output node 310T is provided on the read bit line RBL in response to a read word line RWL and the complement data state 308C of the complement output node 310C. Thus, further explanation of the read control circuit 362 is not provided.

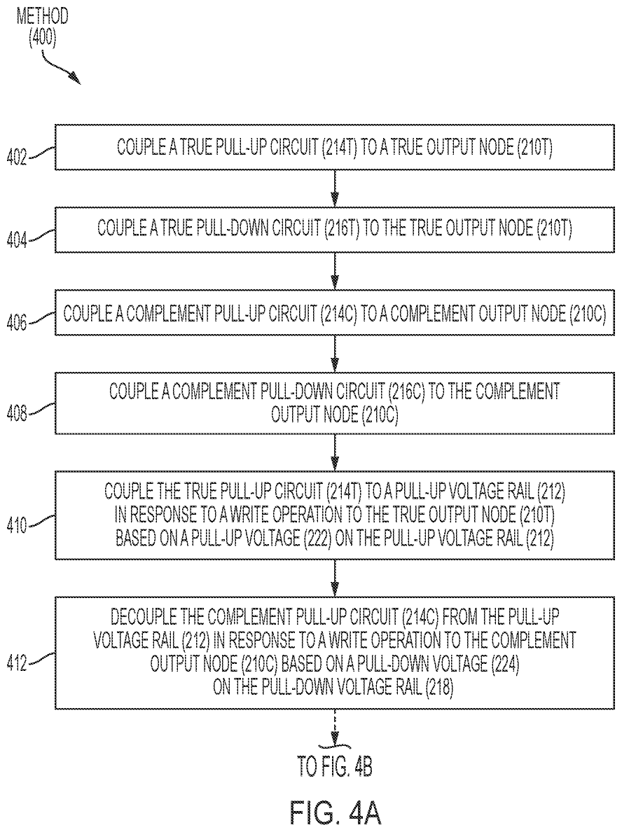

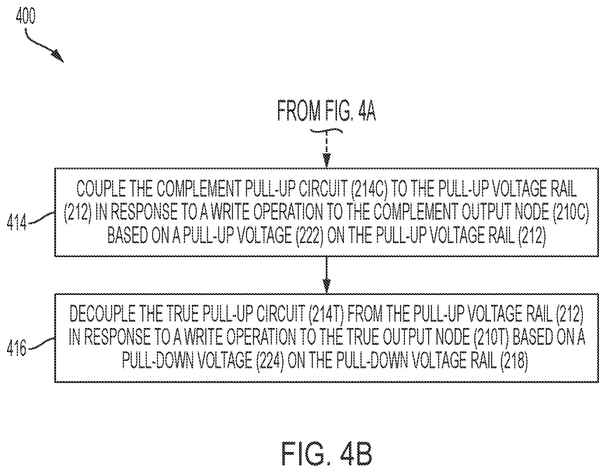

FIGS. 4A and 4B illustrate a flowchart of a method 400 in an SRAM bit cell circuit 200 as shown in FIG. 2A in a memory array circuit 500 as shown in FIG. 5 including a plurality of the SRAM bit cell circuits 200. The method 400 includes coupling a true pull-up circuit 214T to a true output node 210T (block 402) and coupling a true pull-down circuit 216T to the true output node 210T (block 404). The method includes coupling a complement pull-up circuit 214C to a complement output node 210C (block 406) and coupling a complement pull-down circuit 216C to the complement output node 210C (block 408). The method further includes coupling the true pull-up circuit 214T to a pull-up voltage rail 212 in response to a write operation to the true output node 210T based on a pull-up voltage 222 on the pull-up voltage rail 212 (block 410). The method includes decoupling the complement pull-up circuit 214C from the pull-up voltage rail 212 in response to a write operation to the complement output node 210C based on a pull-down voltage 224 on the pull-down voltage rail 218 (block 412). In another example, the method 400 may include coupling the complement pull-up circuit 214C to a pull-up voltage rail 212 in response to a write operation to the complement output node 210C based on a pull-up voltage 222 on the pull-up voltage rail 212 (block 414). The method includes decoupling the true pull-up circuit 214T from the pull-up voltage rail 212 in response to a write operation to the true output node 210T based on a pull-down voltage 224 on the pull-down voltage rail 218 (block 416).

FIG. 5 is a schematic diagram of a memory array circuit 500 including an array of SRAM bit cell circuits 502(0,0)-502(M,N) that may be either the SRAM bit cell circuits 200 in FIGS. 2A-2B or the SRAM bit cell circuits 300 in FIGS. 3A-3B. The SRAM bit cell circuits 502(0,0)-502(M,N) include write control circuits configured to reduce or avoid write contention according to the method in FIGS. 4A and 4B. The memory array circuit 500 includes SRAM bit cell circuits 502(0,0)-502(M,N) that store data that can be accessed (e.g., by a processing circuit (not shown)) with read operations and write operations. The memory array circuit 500 is an (M+1)×(N+1) array of SRAM bit cell circuits 502(0,0)-502(M,N) organized in rows 504(0)-504(M) and columns 506(0)-506(N). Each of the rows 504(0)-504(M) includes a write word line 508(0)-508(M) coupled to all the SRAM bit cell circuits 502(0,0)-502(M,N) and to a row control circuit 510 configured to provide write word signals WWL(0)-WWL(M) to the SRAM bit cell circuits 502(0,0)-502(M,N). Each of the columns 506(0)-506(N) of the memory array circuit 500 includes a true write bit line 512(0)-512(N) and a complement write bit line 514(0)-514(N). The true write bit lines 512(0)-512(N) are configured to provide true write bit signals WBL(0)-WBL(N) and the complement write bit lines 514(0)-514(N) are configured to provide complement write bit signals WBLB(0)-WBLB(N) to the SRAM bit cell circuits 502(0,0)-502(M,N) in the columns 506(0)-506(N). The true write bit signals WBL(0)-WBL(N) and the complement write bit signals WBLB(0)-WBLB(N) may be generated by a column control circuit 516.

Write operations to the SRAM bit cell circuits 200 and 300 were described with reference to FIGS. 2A-2B and 3A-3B above. Write operations of the memory array circuit 500 are described below for the memory array circuit 500 including the SRAM bit cell circuits 502(0,0)-502(M,N) corresponding to the SRAM bit cell circuits 200 in FIGS. 2A-2B. Thus, references may be made to features illustrated in FIGS. 2A, 2B, and 5. When the write word signals WWL(0)-WWL(M) on the write word lines 508(0)-508(M) are in an inactive state, data is not written into any of the SRAM bit cell circuits 502(0,0)-502(M,N). For write operations to the row 504(0) of the memory array circuit 500, as an example, the write word signal WWL(0) is generated on the write word line 508(0) in an active state, which may correspond to a logic ‘1’ or a logic ‘0’. In a first example, a write operation to the SRAM bit cell circuits 502(0,0)-502(0,N) in a first row 504(0) may be in response to the complement write bit signals WBLB(0)-WBLB(N) comprising or being in a second write state and the true write bit signals WBL(0)-WBL(N) comprising a first write state. In this regard, a logic ‘1’ may be written into the true output nodes 210T of all the SRAM bit cell circuits 502(0,0)-502(0,N) and a logic ‘0’ may be written into the complement output nodes 210C of all the SRAM bit cell circuits 502(0,0)-502(0,N).

In a second example, a write operation to the SRAM bit cell circuits 502(0,0)-502(0,N) in the first row 504(0) may be in response to the complement write bit signals WBLB(0)-WBLB(N) comprising or being in the first write state and the true write bit signals WBL(0)-WBL(N) comprising the second write state. In this regard, a logic ‘0’ may be written into the true output nodes 210T of all the SRAM bit cell circuits 502(0,0)-502(0,N) and a logic ‘1’ may be written into the complement output nodes 210C of all the SRAM bit cell circuits 502(0,0)-502(0,N).

An example of a write operation not described above may include a partial write to any of the rows 504(0)-504(M). In this example, it may be desired that only a first plurality including the SRAM bit cell circuits 502(0,0)-502(0,X) are written and a second plurality including the SRAM bit cell circuits 502(0,X+1)-502(0,N) are masked from the write operation. In the SRAM bit cell circuits 502(0,0)-502(0,X), in response to the write word signal WWL(0) comprising the active state, the true write control circuits 226 are configured to couple the true pull-up circuits 214T to the pull-up voltage rail 212 in response to the complement write bit signals WBLB(0)-WBLB(X) comprising the second write state. In addition, the complement write control circuits 228 are configured to decouple the complement pull-up circuits 214C from the pull-up voltage rail 212 in response to the true write bit signals WBL(0)-WBL(X). In the SRAM bit cell circuits 502(0,X+1)-502(0,N), in response to the write word signal WWL(0) comprising the active state, the true write control circuits 226 are configured to couple the true pull-up circuits 214T to the pull-up voltage rail 212 in response to the complement write bit signals WBLB(0)-WBLB(X) comprising the second write state. In addition, the complement write control circuits 228 are configured to couple the complement pull-up circuits 214C to the pull-up voltage rail 212 in response to the true write bit signals WBL(0)-WBL(X). During the partial write operation, the write mask circuits 248 in the SRAM bit cell circuits 502(0,0)-502(0,X) couple the complement output nodes 210C to the pull-down voltage rail 218 in accordance with the write operation. However, the write mask circuits 248 in the SRAM bit cell circuits 502(0,X+1)-502(0,N) do not couple either the true output nodes 210T or the complement output nodes 210C to the pull-down voltage rail 218. In this regard, a logic ‘1’ is written to the SRAM bit cell circuits 502(0,0)-502(0,X) but new data is not written to the SRAM bit cell circuits 502(0,X+1)-502(0,N) because the SRAM bit cell circuits 502(0,X+1)-502(0,N) may be masked from the write operation by the write mask circuits 248.

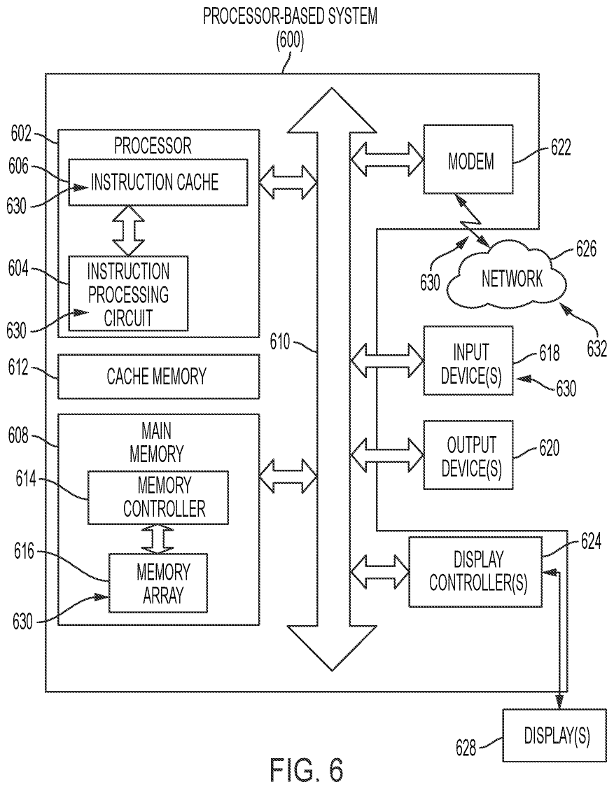

FIG. 6 is a block diagram of an exemplary processor-based system 600 that includes a processor 602 (e.g., a microprocessor) that includes an instruction processing circuit 604. The processor-based system 600 may be a circuit or circuits included in an electronic board card, such as a printed circuit board (PCB), a server, a personal computer, a desktop computer, a laptop computer, a personal digital assistant (PDA), a computing pad, a mobile device, or any other device, and may represent, for example, a server, or a user's computer. In this example, the processor-based system 600 includes the processor 602. The processor 602 represents one or more general-purpose processing circuits, such as a microprocessor, central processing unit, or the like. More particularly, the processor 602 may be an EDGE instruction set microprocessor, or other processor implementing an instruction set that supports explicit consumer naming for communicating produced values resulting from execution of producer instructions. The processor 602 is configured to execute processing logic in instructions for performing the operations and steps discussed herein. In this example, the processor 602 includes an instruction cache 606 for temporary, fast access memory storage of instructions accessible by the instruction processing circuit 604. Fetched or prefetched instructions from a memory, such as from a main memory 608 over a system bus 610, are stored in the instruction cache 606. Data may be stored in a cache memory 612 coupled to the system bus 610 for low-latency access by the processor 602. The instruction processing circuit 604 is configured to process instructions fetched into the instruction cache 606 and process the instructions for execution.

The processor 602 and the main memory 608 are coupled to the system bus 610 and can intercouple peripheral devices included in the processor-based system 600. As is well known, the processor 602 communicates with these other devices by exchanging address, control, and data information over the system bus 610. For example, the processor 602 can communicate bus transaction requests to a memory controller 614 in the main memory 608 as an example of a slave device. Although not illustrated in FIG. 6, multiple system buses 610 could be provided, wherein each system bus constitutes a different fabric. In this example, the memory controller 614 is configured to provide memory access requests to a memory array 616 in the main memory 608. The memory array 616 is comprised of an array of storage bit cells for storing data. The main memory 608 may be a read-only memory (ROM), flash memory, dynamic random-access memory (DRAM), such as synchronous DRAM (SDRAM), etc., and a static memory (e.g., flash memory, static random-access memory (SRAM), etc.), as non-limiting examples.

Other devices can be connected to the system bus 610. As illustrated in FIG. 6, these devices can include the main memory 608, one or more input device(s) 618, one or more output device(s) 620, a modem 622, and one or more display controllers 624, as examples. The input device(s) 618 can include any type of input device, including but not limited to input keys, switches, voice processors, etc. The output device(s) 620 can include any type of output device, including but not limited to audio, video, other visual indicators, etc. The modem 622 can be any device configured to allow exchange of data to and from a network 626. The network 626 can be any type of network, including but not limited to a wired or wireless network, a private or public network, a local area network (LAN), a wireless local area network (WLAN), a wide area network (WAN), a BLUETOOTH™ network, and the Internet. The modem 622 can be configured to support any type of communications protocol desired. The processor 602 may also be configured to access the display controller(s) 624 over the system bus 610 to control information sent to one or more displays 628. The display(s) 628 can include any type of display, including but not limited to a cathode ray tube (CRT), a liquid crystal display (LCD), a plasma display, etc.

The processor-based system 600 in FIG. 6 may include a set of instructions 630 to be executed by the processor 602 for any application desired according to the instructions. The instructions 630 may be stored in the main memory 608, processor 602, and/or instruction cache 606 as examples of a non-transitory computer-readable medium 632. The instructions 630 may also reside, completely or at least partially, within the main memory 608 and/or within the processor 602 during their execution. The instructions 630 may further be transmitted or received over the network 626 via the modern 622, such that the network 626 includes computer-readable medium 632.

While the computer-readable medium 632 is shown in an exemplary embodiment to be a single medium, the term “computer-readable medium” should be taken to include a single medium or multiple media (e.g., a centralized or distributed database, and/or associated caches and servers) that stores the one or more sets of instructions. The term “computer-readable medium” shall also be taken to include any medium that is capable of storing, encoding, or carrying a set of instructions for execution by the processing device and that causes the processing device to perform any one or more of the methodologies of the embodiments disclosed herein. The term “computer-readable medium” shall accordingly be taken to include, but not be limited to, solid-state memories, optical medium, and magnetic medium.

The processor 602 in the processor-based system 600 may include, in any of the devices therein, a memory array circuit that includes the SRAM bit cell circuits including write control circuits to decouple one of a true storage circuit and a complement storage circuit from pull-up voltage rail in a write operation to reduce or avoid write contention, as illustrated in FIGS. 2A-3B.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product, or software, that may include a machine-readable medium (or computer-readable medium) having stored thereon instructions, which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes: a machine-readable storage medium (e.g., ROM, random access memory (“RAM”), a magnetic disk storage medium, an optical storage medium, flash memory devices, etc.); and the like.

Unless specifically stated otherwise and as apparent from the previous discussion, it is appreciated that throughout the description, discussions utilizing terms such as “processing,” “computing,” “determining,” “displaying,” or the like, refer to the action and processes of a computer system, or similar electronic computing device, that manipulates and transforms data and memories represented as physical (electronic) quantities within the computer system's registers into other data similarly represented as physical quantities within the computer system memories or registers or other such information storage, transmission, or display devices.

The algorithms and displays presented herein are not inherently related to any particular computer or other apparatus. Various systems may be used with programs in accordance with the teachings herein, or it may prove convenient to construct more specialized apparatuses to perform the required method steps. The required structure for a variety of these systems will appear from the description above. In addition, the embodiments described herein are not described with reference to any particular programming language. It will be appreciated that a variety of programming languages may be used to implement the teachings of the embodiments as described herein.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The components of the distributed antenna systems described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends on the particular application, design choices, and/or design constraints imposed on the overall system. Skilled artisans may implement the described functionality in varying ways for each particular application, but such implementation decisions should not be interpreted as causing a departure from the scope of the present embodiments.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA), or other programmable logic device, a discrete gate or transistor logic, discrete hardware components, or any combination thereof designed to perform the functions described herein. Furthermore, a controller may be a processor. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The embodiments disclosed herein may be embodied in hardware and in instructions that are stored in hardware, and may reside, for example, in RAM, flash memory, ROM, Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. Those of skill in the art will also understand that information and signals may be represented using any of a variety of technologies and techniques. For example, data, instructions, commands, information, signals, bits, symbols, and chips, that may be references throughout the above description, may be represented by voltages, currents, electromagnetic waves, magnetic fields, or particles, optical fields or particles, or any combination thereof.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that any particular order be inferred.

It will be apparent to those skilled in the art that various modifications and variations can be made without departing from the spirit or scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A memory array circuit comprising a plurality of static random-access memory (SRAM) bit cell circuits, each of the SRAM bit cell circuits, comprising:
a true storage circuit, comprising:
a true output node;
a true pull-up circuit coupled to the true output node; and
a true pull-down circuit coupled to the true output node;
a complement storage circuit, comprising:
a complement output node;
a complement pull-up circuit coupled to the complement output node; and
a complement pull-down circuit coupled to the complement output node; and
a write control circuit comprising:
a true write control circuit coupled between the true pull-up circuit and a pull-up voltage rail; and
a complement write control circuit coupled between the complement pull-up circuit and the pull-up voltage rail;
the write control circuit configured to:
couple the true pull-up circuit to the pull-up voltage rail in response to a write operation to the true output node based on a pull-up voltage on the pull-up voltage rail; and
decouple the complement pull-up circuit from the pull-up voltage rail in response to a write operation to the complement output node based on a pull-down voltage on a pull-down voltage rail.

2. The memory array circuit of claim 1, wherein the write control circuit is further configured to:
decouple the true pull-up circuit from the pull-up voltage rail in response to a write operation to the true output node based on the pull-down voltage on the pull-down voltage rail; and
couple the complement pull-up circuit to the pull-up voltage rail in response to a write operation to the complement output node based on the pull-up voltage on the pull-up voltage rail.

3. The memory array circuit of claim 2, wherein, in response to a write word signal comprising an active state:
the true write control circuit is further configured to couple the true pull-up circuit to the pull-up voltage rail in response to a complement write bit signal comprising a first write state; and
the complement write control circuit is further configured to decouple the complement pull-up circuit from the pull-up voltage rail in response to a true write bit signal comprising a second write state.

4. The memory array circuit of claim 3, wherein in response to the write word signal comprising the active state:
the true write control circuit is further configured to decouple the pull-up circuit from the pull-up voltage rail in response to the complement write bit signal comprising the second write state; and
the complement write control circuit is further configured to couple the complement pull-up circuit to the pull-up voltage rail in response to the true write bit signal comprising the first write state.

5. The memory array circuit of claim 4, wherein in response to the write word signal comprising an inactive state:
the true write control circuit is further configured to couple the true pull-up circuit to the pull-up voltage rail; and
the complement write control circuit is further configured to couple the complement pull-up circuit to the pull-up voltage rail.

6. The memory array circuit of claim 5, wherein in response to the write word signal comprising the active state:
the true write control circuit is further configured to couple the pull-up circuit to the pull-up voltage rail in response to the complement write bit signal comprising the second write state; and
the complement write control circuit is further configured to couple the complement pull-up circuit to the pull-up voltage rail in response to the true write bit signal comprising the second write state.

7. The memory array circuit of claim 3, wherein:
the true write control circuit comprises:
a first transistor configured to couple the true pull-up circuit to the pull-up voltage rail in response to the complement write bit signal; and
a second transistor configured to couple the true pull-up circuit to the pull-up voltage rail in response to the write word signal; and
the complement write control circuit comprises:
a third transistor configured to couple the complement pull-up circuit to the pull-up voltage rail in response to the true write bit signal; and
a fourth transistor configured to couple the complement pull-up circuit to the pull-up voltage rail in response to the write word signal.

8. The memory array circuit of claim 7, the write control circuit further comprising a write mask circuit comprising:
a fifth transistor configured to couple the true output node to a write mask node in response to the true write bit signal comprising the second write state;
a sixth transistor configured to couple the complement output node to the write mask node in response to the complement write bit signal comprising the second write state; and
a seventh transistor configured to couple the write mask node to the pull-down voltage rail in response to the write word signal comprising the active state.

9. The memory array circuit of claim 8, the write mask circuit configured to:
couple the complement output node to the pull-down voltage rail in response to the write operation to the complement output node based on the pull-down voltage on the pull-down voltage rail; and
couple the true output node to the pull-down voltage rail in response to the write operation to the true output node based on the pull-down voltage on the pull-down voltage rail.

10. The memory array circuit of claim 1, further comprising a read control circuit configured to couple a read bit line to the pull-down voltage rail in response to a read word operation based on a complement data state on the complement output node.

11. The memory array circuit of claim 8, wherein:
the first to fourth transistors comprise P-type metal-oxide-semiconductor (MOS) (PMOS) transistors; and
the fifth to seventh transistors comprise N-type MOS (NMOS) transistors.

12. The memory array circuit of claim 1, wherein:
the true storage circuit further comprises a true input node coupled to the complement output node; and
the complement storage circuit further comprises a complement input node coupled to the true output node.

13. The memory array circuit of claim 6, further comprising:
the plurality of SRAM bit cell circuits disposed in rows of SRAM bit cell circuits and columns of SRAM bit cell circuits;
in each row of SRAM bit cell circuits, a write word line coupled to each of the SRAM bit cell circuits in the row and configured to provide the write word signal;
in each column of SRAM bit cell circuits:
a complement write bit line coupled to each of the SRAM bit cell circuits in the column and configured to provide the complement write bit signal; and
a true write bit line coupled to each of the SRAM bit cell circuits in the column and configured to provide the true write bit signal;
wherein, in response to:
the true write bit signal comprising the active state on the true write bit line in a first row of the rows of SRAM bit cell circuits;
the complement write bit signal comprising the first write state in each of the columns of SRAM bit cell circuits;
the true write bit signal comprising the second write state on the true write bit line in a first plurality of the columns of SRAM bit cell circuits; and
the true write bit signal comprising the first write state on the true write bit line in a second plurality of the columns of SRAM bit cell circuits; and
write to each of the SRAM bit cell circuits in the first row and in the first plurality of the columns of SRAM bit cell circuits.

14. A method in a memory array circuit comprising a plurality of static random-access memory (SRAM) bit cell circuits, the method comprising:
coupling a true pull-up circuit to a true output node;
coupling a true pull-down circuit to the true output node;
coupling a complement pull-up circuit to a complement output node;
coupling a complement pull-down circuit to the complement output node;
coupling the true pull-up circuit to a pull-up voltage rail in response to a write operation to the true output node based on a pull-up voltage on the pull-up voltage rail; and
decoupling the complement pull-up circuit from the pull-up voltage rail in response to a write operation to the complement output node based on a pull-down voltage on a pull-down voltage rail.

15. A memory array circuit comprising a plurality of static random-access memory (SRAM) bit cell circuits, each of the SRAM bit cell circuits, comprising:
a true storage circuit, comprising:
a true output node;
a true pull-up circuit coupled to the true output node; and
a true pull-down circuit coupled to the true output node;
a complement storage circuit, comprising:
a complement output node;
a complement pull-up circuit coupled to the complement output node; and
a complement pull-down circuit coupled to the complement output node; and
a write control circuit comprising:
a true write control circuit coupled between the true pull-down circuit and a pull-down voltage rail; and
a complement write control circuit coupled between the complement pull-down circuit and the pull-down voltage rail;
the write control circuit configured to:
couple the true pull-down circuit to the pull-down voltage rail in response to a write operation to the true output node based on a pull-down voltage on the pull-down voltage rail; and
decouple the complement pull-down circuit from the pull-down voltage rail in response to a write operation to the complement output node based on a pull-up voltage on a pull-up voltage rail.

16. The memory array circuit of claim 15, wherein the write control circuit is further configured to:
decouple the true pull-down circuit from the pull-down voltage rail in response to a write operation to the true output node based on the pull-up voltage on the pull-up voltage rail; and
couple the complement pull-up circuit to the pull-down voltage rail in response to a write operation to the complement output node based on the pull-down voltage on the pull-down voltage rail.

17. The memory array circuit of claim 16, wherein, in response to a write word signal comprising an active state:
the true write control circuit is further configured to couple the pull-down circuit to the pull-down voltage rail in response to a complement write bit signal comprising a first state; and
the complement write control circuit is further configured to decouple the complement pull-down circuit from the pull-down voltage rail in response to a true write bit signal comprising a second state.

18. The memory array circuit of claim 17, wherein in response to the write word signal comprising the active state:
the true write control circuit is further configured to decouple the pull-down circuit from the pull-down voltage rail in response to the complement write bit signal comprising the second state; and
the complement write control circuit is further configured to couple the complement pull-down circuit to the pull-down voltage rail in response to the true write bit signal comprising the first state.

19. The memory array circuit of claim 18, wherein in response to the write word signal comprising an inactive state:
the true write control circuit is further configured to couple the true pull-down circuit to the pull-down voltage rail; and
the complement write control circuit is further configured to couple the complement pull-down circuit to the pull-down voltage rail.

20. The memory array circuit of claim 19, wherein in response to the write word signal comprising the active state:
the true write control circuit is further configured to couple the true pull-down circuit to the pull-down voltage rail in response to the complement write bit signal comprising the second state; and
the complement write control circuit is further configured to couple the complement pull-down circuit to the pull-down voltage rail in response to the true write bit signal comprising the second state.

21. The memory array circuit of claim 17, wherein:
the true write control circuit comprises:
a first transistor configured to couple the true pull-down circuit to the pull-down voltage rail in response to the complement write bit signal; and
a second transistor configured to couple the true pull-down circuit to the pull-down voltage rail in response to the write word signal; and
the complement write control circuit comprises:
a third transistor configured to couple the complement pull-down circuit to the pull-down voltage rail in response to the true write bit signal; and
a fourth transistor configured to couple the complement pull-down circuit to the pull-down voltage rail in response to the write word signal.

22. The memory array circuit of claim 21, the write control circuit further comprising a write mask circuit comprising:
a fifth transistor configured to couple the true data output node to a write mask node in response to the true write bit signal comprising the second state;
a sixth transistor configured to couple the complement data output node to the write mask node in response to the complement write bit signal comprising the second state; and
a seventh transistor configured to couple the write mask node to the pull-up voltage rail in response to the write word signal comprising the active state.

23. The memory array circuit of claim 22, the write mask circuit configured to:
couple the complement output node to the pull-up voltage rail in response to the write operation to the complement output node based on the pull-up voltage on the pull-up voltage rail; and
couple the true output node to the pull-up voltage rail in response to the write operation to the true output node based on the pull-up voltage on the pull-up voltage rail.

24. The memory array circuit of claim 22 wherein:
the first to fourth transistors comprise N-type metal-oxide-semiconductor (MOS) (NMOS) transistors; and
the fifth to seventh transistors comprise P-type MOS (PMOS) transistors.

25. A method in a memory array circuit comprising a plurality of static random-access memory (SRAM) bit cell circuits, the method comprising:
coupling a true pull-up circuit to a true output node;
coupling a true pull-down circuit to the true output node;
coupling a complement pull-up circuit to a complement output node;
coupling a complement pull-down circuit to the complement output node;
coupling the true pull-down circuit to a pull-down voltage rail in response to a write operation to the true output node based on a pull-down voltage on the pull-down voltage rail; and
decoupling the complement pull-down circuit from the pull-down voltage rail in response to a write operation to the complement output node based on a pull-up voltage on a pull-up voltage rail.
